(19) United States
(12) Patent Application Publication
(10) Pub. No.: US 2021/0141972 A1
(43) Pub. Date: May 13, 2021

(54) METHOD FOR GENERATING AN IMAGE DATA SET FOR A COMPUTER-IMPLEMENTED SIMULATION

(71) Applicant: Ford Global Technologies, LLC, Dearborn, MI (US)

(72) Inventors: Turgay Isik Aslandere, Aachen (DE); Matthias Christian Reiter, Aachen (DE)

(73) Assignee: Ford Global Technologies, LLC, Dearborn, MI (US)

(21) Appl. No.: 17/091,815

(22) Filed: Nov. 6, 2020

(30) Foreign Application Priority Data
Nov. 7, 2019 (DE) 102019130032.0

(51) Int. Cl. G06F 30/20; G06N 3/04; G06N 3/08

(52) U.S. Cl. CPC G06F 30/20; G06N 3/088; G06N 3/0454

(57) ABSTRACT

A method for generating an image data set for a computer-implemented simulation includes reading kinematic data representative of positions of a light source, velocities of the light source, accelerations of the light source, or a combination thereof. The method further includes displacing the light source according to the kinematic data, acquiring light data of the light source, compiling the light data and the associated kinematic data to form a light data set, and training an artificial neural network using the light data set to generate a supplementary data set. The method includes generating the supplementary data set using the trained artificial neural network, and generating the image data set using a raw image data set according to the computer-implemented simulation and the supplementary data set.

### CROSS-REFERENCE TO RELATED APPLICATIONS

This application claims priority to and the benefit of DE 102019130032.0 filed on Nov. 7, 2019. The disclosure of the above application is incorporated herein by reference.

### FIELD

The disclosure relates to a method for generating an image data set for a computer-implemented simulation. Furthermore, the disclosure relates to a computer program product, a system, and a test stand as well as a data processing unit for such a system.

### BACKGROUND

The statements in this section merely provide background information related to the present disclosure and may not constitute prior art.

Motor vehicles can be designed for so-called autonomous driving. An autonomously driving motor vehicle is a self-driving motor vehicle which can drive, steer, and park without influence of a human driver (highly automated driving or autonomous driving). In the case in which no manual control is used on the part of the driver, the term robot automobile is also used. The driver seat can then remain empty; the steering wheel, brake pedal, and accelerator pedal are possibly not present.

Such autonomous motor vehicles can perceive their environment with the aid of various sensors and can determine their own position and that of other road users from the acquired information, set out for a destination in cooperation with the navigation software, and avoid collisions on the way there.

To test such automated driving, the motor vehicles are tested in the real world. However, this is a costly process, and the risk of accidents is high. To avoid accidents and reduce costs simultaneously, tests in the computer-generated virtual environments, for example, tests in virtual cities, can be employed. VR technology (virtual reality technology) together with a virtual environment opens up many options. The main advantage of VR technology is that it permits a user, for example an engineer, to be part of the tests, to interact with the test scenario, or to interact with the configuration parameters.

Such tests also comprise simulating night driving including the light or illumination conditions caused by the motor vehicle lighting system. The light or illumination conditions, induced by the motor vehicle lighting system, such as headlights, turn signals, rear and/or brake lights, are simulated by software tools. However, such software tools supply data representative of simulated light beams with limited accuracy.

A driving simulator, comprising a display surface for displaying a driving simulation, is known from German Patent Publication No. DE 10 2017 126 741 B3, wherein an illumination device is provided to generate dazzling effects. The illumination device comprises at least one light display, which is movable mechanically along the display surface via a movement device.

A method for shader-based illumination simulation of technical illumination systems is known from German Patent Publication No. DE 10 2005 061 590 A1. In a first phase, a projection of an LSV texture in the virtual scenario is carried out by means of projective texture mapping according to the projection parameters, which are derived from the aperture angles of the light source resulting in an asymmetrical projection, wherein the calculation of the texture coordinates for the imaging of the LSV texture on the polygon model of the virtual scenario takes place in a vertex shader, in which the corresponding texture coordinates of the projected LSV texture are calculated for each corner point of the polygon model. In the second phase, a color calculation is carried out for every pixel to represent the illumination of the virtual scenario by the simulated light sources, wherein grayscale tones for a true color representation or color values from an HSV color model for a false color representation are used for the reproduction of the illumination.

A further driving simulator is known from Chinese Patent Publication No. CN 205104079 U, in which an image data set is displayed on a display device.

### SUMMARY

This section provides a general summary of the disclosure and is not a comprehensive disclosure of its full scope or all of its features.

In one form, the present disclosure provides a method for generating an image data set for a computer-implemented simulation, having the following steps:

reading in kinematic data representative of positions and/or velocities and/or accelerations of a light source,

displacing the light source according to the kinematic data, acquiring light data of the light source,

compiling the light data and the associated kinematic data to form a light data set,

training an artificial neural network using the light data set to generate a supplementary data set,

generating the supplementary data set using the trained artificial neural network, and

generating the image data set using a raw image data set according to the computer-implemented simulation and the supplementary data set.

A light data set, the light data of which are based on real measurements which were obtained using a test stand having a real light source, is thus used for training the artificial neural network. The light source can be, e.g., a headlight, a turn signal, a rear light, or a brake light of a motor vehicle or also the illumination of a nonmotorized road user, for example a bicyclist. It can be provided here that movement patterns are simulated by displacing the light source, as they occur in reality during operation of motor vehicles. After completion of the training phase of the artificial neural network, it is then used to generate the supplementary data set, which is representative of the light or illumination conditions, for example in dependence on a specific driving situation. In other words, in addition to the light data, the kinematic data are also taken into consideration to determine the supplementary data set. The supplementary data set is then fused with raw image data which originate from the current computer-implemented simulation and are visualized for a user of a driving simulator by a display device, such as a display screen. Instead of the raw image data set, however, the image data set having the supplementary data set embedded by fusion is visualized for the user of the driving simulator.

Because real data based on real measurements are used to train the artificial neural network, the simulation of light or illumination conditions can be improved.

According to one form, the light source is displaced by a robot according to the kinematic data. The robot can be, for example a six-axis industrial robot, on the manipulator end of which the light source is arranged. The light source can thus be moved according to the kinematic data particularly simply by using the robot.

According to another form, the artificial neural network is trained by unsupervised learning. In this case, unsupervised learning is understood as a variant of machine learning without target values known beforehand and without reward by the environment. A learning algorithm attempts to recognize patterns in the input data which deviate from unstructured noise. The artificial neural network orients itself on the similarity to the input values and adapts its weighting factors accordingly. The expenditure for the preparation of the learning data can be reduced in this way, which are applied to the artificial neural network during the training phase. However, the artificial neural network can also be trained by supervised learning, semi-supervised learning, or reinforcement learning.

In one form, a generative adversarial network (GAN) is used as an artificial neural network. A GAN is understood as an arrangement consisting of two artificial neural networks, which carry out a zero-sum game during the training phase. The first artificial neural network, the generator, creates candidates, while the second artificial neural network, the discriminator, evaluates the candidates. Typically, the generator maps latent variables from a vector on the desired result space. The goal of the generator is to learn to generate results according to a specific distribution. In contrast, the discriminator is trained to differentiate the results of the generator from the data from the real, predetermined distribution. The target function of the generator is to generate results which the discriminator cannot differentiate. The generated distribution will thus gradually converge with the real distribution. Supplementary data sets can thus be generated, which can hardly be differentiated from the original light data and are therefore particularly well suited for simulations.

Furthermore, the disclosure includes a computer program product, a system, and a test stand as well as a data processing unit for such a system.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a schematic illustration of components of a system generating an image data set for a computer-implemented simulation in accordance with the present disclosure;

FIG. 2 shows a schematic illustration of further details of the system shown in FIG. 1 in accordance with the present disclosure; and

FIG. 3 shows a schematic illustration of a method sequence for operation of the system shown in FIG. 1 in accordance with the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

Reference is firstly made to FIG. 1.

A system 2 is shown for generating an image data set (identified as “BDS” in the figures) for a computer-implemented simulation of a virtual environment.

The representation and simultaneous perception of reality and its physical properties in an interactive virtual environment computer generated in real time, is referred to as virtual reality, abbreviated VR.

In one form, to generate the feeling of immersion, special output devices, for example, virtual reality headsets, are used to represent the virtual environment. To give a three-dimensional impression, two images from different perspectives are generated and displayed (stereo projection).

In one form, special input devices (not shown) are used for the interaction with the virtual world, for example, a 3D mouse, a data glove, or a flystick. In one form, the flystick is used for navigation with an optical tracking system, where infrared cameras permanently report the position in space to the system 2 by acquiring markers on the flystick, so that a user can move freely without wiring. Optical tracking systems can also be used for acquiring tools and complete human models to be able to manipulate them within the VR scenario in real time.

In one form, some input devices give the user force feedback on the hands or other body parts, so that the user can orient themselves by way of haptics and sensors as a further sensation in the virtual environment.

In one form, software developed especially for this purpose is used for generating a virtual environment. The software can compute complex three-dimensional worlds in real time, i.e., at least 25 images per second, in stereo separately for left and right eye of the user. In one form, the value varies depending on the application—a driving simulation, for example, requires at least 60 images per second, to avoid nausea (simulator sickness).

Of the components of the system 2, a test stand 4, a driving simulator 6, a human machine interface (HMI) 8, and a data processing unit 10 (i.e., a data processor/data process module) are shown in FIG. 1.

In one form, the system 2 and the test stand 4, the driving simulator 6, the HMI 8, and the data processing unit 10 can have hardware (e.g., processor(s), memory, server(s), display(s), etc.) and/or software components/programs for the tasks and functions described below.

In one form, the system 2 and the test stand 4, the driving simulator 6, the HMI 8, and the data processing unit 10 are designed for data exchange according to a transmission control protocol and the internet protocol (TCP/IP), user datagram protocol (UDP), or controller area network (CAN) protocol.

In one form, the test stand 4 is located in a darkened room to preclude interference due to other light sources and comprises a robot 12 having a light source 14 arranged on its manipulator end, four cameras 16a, 16b, 16c, 16d, and a computer 18.

In one form, the robot 12 is a six-axis industrial robot, which can be activated by the computer 18 in such a way that the light source 14 can be displaced according to kinematic data KD representative of positions, velocities, and/or accelerations.

In one form, the light source 14 can be a headlight, a turn signal, a rear light, or a brake light of a motor vehicle, for example of a passenger vehicle, or also the illumination of a nonmotorized road user, for example a bicyclist.

In one form, light data (identified as “LD” in the figures) of the light source 14 can use the cameras 16a, 16b, 16c, 16d, while the light source 14 is displaced by the robot 12 according to the kinematic data (identified as “KD” in the figures) in order to simulate a movement of a motor vehicle or nonmotorized road user.

In one form, the computer 18 is in turn configured to read in the light data LD and then compile the read-in light data LD and the associated kinematic data KD to form a light data set (identified as “LDS” in the figures). The light data set LDS is provided—as will be explained later—to the data processing unit 10.

In one form, the driving simulator 6 is a simulation software or a technical assembly of various components which are used to simulate driving processes. The driving simulator 6 can be designed to simulate different motor vehicles, e.g., cars, trucks, or buses. In the present exemplary form, the driving simulator 6 is designed to simulate a passenger vehicle.

In one form, the driving simulator 6 can have a steering wheel, pedals, and other switching elements as input devices. However, some driving simulators 6 may also be operated using a mouse, a keyboard, a gamepad, or a joystick. In some forms, the driving simulators 6 use force feedback for a more realistic driving feeling. Complex driving simulators 6 attempt to simulate the control area as faithfully to the original as possible.

In one form, the driving simulators 6 also offer, in addition to the output via one or more monitors, the output in a virtual reality using the HMI 8 operated by the user, which has a data-exchanging connection to the driving simulator 6 and is configured as a head-mounted display, which the user wears on the head during a simulated drive.

In one form, the driving simulator 6 is configured to read and evaluate in a VR data set representative of a virtual environment in order to generate the virtual environment. In one form, the driving simulator 6 is configured to provide a raw image data set (identified as “RDS” in the figure) based on a virtual environment, which takes into consideration a current viewing direction of the user and is then visualized to the user by the HMI 8.

In one form, the data processing unit 10 is configured to provide an image data set BDS, for example for visualization using the HMI 8. The image data set BDS is based on the raw image data set RDS, supplemented with a supplementary data set (identified as “EDS” in the figure), representative of light or illumination conditions, and induced by the light source 14.

In one form, to generate the supplementary data set EDS, the data processing unit 10 has an artificial neural network 20, which is explained with additional reference to FIG. 2.

The artificial neural network 20 shown in FIG. 2 is a GAN (generative adversarial network). However, different variants of the GANs can be used in order to transform the probability distribution, for example the cycle GANs. The artificial neural network 20 thus includes two artificial neural networks.

The first artificial neural network is configured here as a generator 22 and the second artificial neural network is configured as a discriminator 24.

In one form, during the training phase, the generator 22 and the discriminator 24 carry out a zero-sum game. In this case, the generator 22 generates candidate sets (identified as “KS” in the figure), for example based on random values and the kinematic data KD, while the discriminator 24 evaluates the candidate sets KS. For this purpose, the discriminator 24 carries out a comparison of the candidate sets KS to the light data set LDS.

The discriminator 24 provides a logical variable (identified as “T” in the figures) as an output variable, to which the value logical one is assigned during the training phase if the discriminator 24 cannot differentiate a candidate set KS from a light data set LDS within predetermined limits or accuracies. Otherwise, the logical variable T is assigned the value logical zero during the training phase.

In other words, the generator 22 is trained to generate results, i.e., supplementary data sets EDS, according to a specific distribution, i.e., the light data sets LDS. In contrast, the discriminator 24 is trained to differentiate the results of the generator 22 from the real, predetermined distribution. In the course of the training phase, the generated distribution thus gradually converges with the real distribution.

In this case, in the present exemplary form the artificial neural network 20, i.e., the generator 22 and the discriminator 24, is trained by unsupervised learning. In some forms, training can also take place by supervised learning, semi-supervised learning, or reinforcement learning.

A method sequence for the operation of the system 2 will now be explained with additional reference to FIG. 3.

In a first step S100 of a data acquisition phase of the method, the computer 18 of the test stand 4 reads in the kinematic data KD, which are representative of positions and/or velocities and/or accelerations of the light source 14, which are supplied by the driving simulator 6 to the computer 18.

In a further step S200 of the data acquisition phase of the method, the robot 12 of the test stand 4 displaces the light source 14 according to the kinematic data KD.

In a further step S300 of the data acquisition phase of the method, the light data LD of the light source 14 are acquired using the cameras 16a, 16b, 16c, 16d and read in by the computer 18, while the light source is displaced by the robot 12 according to the kinematic data KD.

In a further step S400 of the data acquisition phase of the method, the computer 18 associates the acquired light data LD with the associated kinematic data KD and thus forms the light data set LDS.

In a further step S500 of a training phase of the method, the artificial neural network 20 of the data processing unit 10 having the generator 22 and the discriminator 24 is trained by unsupervised learning. For this purpose, the light data set LDS provided by the computer 18, having the light data LD with the associated kinematic data KD, is used.

After completion of the training phase, the artificial neural network 20 having the generator 22 and the discriminator 24 is designed to generate the supplementary data set EDS, for example in dependence on the kinematic data KD.

In a further step S600 of an operating phase of the method, the supplementary data set EDS is generated by the data processing unit 10 using the artificial neural network 20.

In a further step S700 of the operating phase of the method, the data processing unit 10 reads in the raw image data set RDS according to a running computer-implemented simulation and fuses it with the supplementary data set EDS to generate the image data set BDS.

In a further step S800 of the operating phase of the method, the image data set BDS is visualized by the data processing unit 10 on the driving simulator 6 and/or the HMI 8 and to the user there.

In some forms, the sequence of the steps can be different. Furthermore, in some forms, multiple steps can be carried out at the same time or simultaneously. Furthermore, in some forms, individual steps can be skipped or omitted.

Real data based on real measurements can thus be used to train the artificial neural network 20, which improves the simulation of light or illumination conditions.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for generating an image data set for a computer-implemented simulation, the method comprising:
reading kinematic data representative of positions of a light source, velocities of the light source, accelerations of the light source, or a combination thereof;
displacing the light source according to the kinematic data;
acquiring light data of the light source;
compiling the light data and the kinematic data to form a light data set;
training an artificial neural network using the light data set to generate a supplementary data set;
generating the supplementary data set using the trained artificial neural network; and
generating the image data set using a raw image data set according to the computer-implemented simulation and the supplementary data set.

2. The method according to claim 1, wherein the light source is displaced by a robot according to the kinematic data.

3. The method according to claim 1, wherein the artificial neural network is trained by unsupervised learning.

4. The method according to claim 1, wherein the artificial neural network is a generative adversarial network.

5. A computer program product configured to perform the method according to claim 1.

6. A system comprising a test stand including a light source and a data processor, the system configured to:
generate an image data set for a computer-implemented simulation,
read kinematic data representative of positions of the light source, velocities of the light source, accelerations of the light source, or a combination thereof,
displace the light source according to the kinematic data to acquire light data of the light source,
compile the light data and the kinematic data to form a light data set,
train an artificial neural network using the light data set to generate a supplementary data set,
generate the supplementary data set using the trained artificial neural network, and
generate the image data set using a raw image data set according to the computer-implemented simulation and the supplementary data set.

7. The system according to claim 6, wherein the light source is displaceable by a robot according to the kinematic data.

8. The system according to claim 6, wherein the artificial neural network is configured to train by unsupervised learning.

9. The system according to claim 6, wherein the artificial neural network is a generative adversarial network.

10. The system of claim 6, wherein the test stand is configured to read the kinematic data, displace the light source according to the kinematic data, acquire the light data of the light source, and compile the light data and the kinematic data to form the light data set.

11. The system according to claim 10, wherein the test stand further includes a robot for displacing the light source according to the kinematic data.

12. The system of claim 6, wherein the data processor includes the artificial neural network and is configured to train the artificial neural network using the light data set to generate the supplementary data set, generate the supplementary data set using the trained artificial neural network, and generate the image data set using the raw image data set according to the computer-implemented simulation and the supplementary data set.

13. The system according to claim 12, wherein the data processor is configured to train the artificial neural network by unsupervised learning.

14. The system according to claim 12, wherein the artificial neural network is a generative adversarial network.

15. A method for generating an image data set for a computer-implemented simulation, the method comprising:
reading kinematic data representative of a position of a light source, a velocity of the light source, an acceleration of the light source, or a combination thereof;
displacing the light source based on the kinematic data;
acquiring light data associated with the light source;
compiling the light data and the kinematic data to form a light data set;
training a generative adversarial network based on the light data set to generate a supplementary data set;
generating the supplementary data set based on the trained generative adversarial network; and
generating the image data set using a raw image data set and based on the supplementary data set.

16. The method according to claim 15, wherein the light source is displaced by a robot based on the kinematic data.

17. The method according to claim 15, wherein the generative adversarial network is trained by unsupervised learning.

18. A computer program product configured to perform the method according to claim 15.

19. The method according to claim 15, wherein the generative adversarial network includes a generator and a discriminator.

20. The method according to claim 15, wherein the generative adversarial network is trained by one of supervised learning, semi-supervised learning, and reinforcement learning.
